(19) United States
(12) Patent Application Publication
(10) Pub. No.: US 2023/0290767 A1
(43) Pub. Date: Sep. 14, 2023

(54) SEMICONDUCTOR DEVICES

(71) Applicant: Samsung Electronics Co., Ltd., Suwon-si (KR)

(72) Inventors: Jaeha LEE, Yongin-si (KR); Hyeongkyu Kim, Suwon-si (KR)

(73) Assignee: Samsung Electronics Co., Ltd., Suwon-si (KR)

(21) Appl. No.: 18/051,943

(22) Filed: Nov. 2, 2022

(30) Foreign Application Priority Data
Nov. 19, 2021 (KR) 10-2021-0160269

(51) Int. Cl. H01L 27/02; G06F 30/31

(52) U.S. Cl. CPC H01L 27/0207; G06F 30/31

(57) ABSTRACT

A semiconductor device including a standard cell including active patterns extending in a first direction, gate patterns extending in a second direction perpendicular to the first direction, and contact patterns being on the active patterns at opposite sides of the gate patterns, and interconnection line patterns extending in the first direction and spaced apart from each other in the second direction, on the stand cell may be provided. The standard cell may include first and second standard cells that partially overlap each other. A first special boundary may be defined on a cell boundary of the second standard cell in the first standard cell, and a second special boundary may be defined on a cell boundary of the first standard cell in the second standard cell. At least one of the interconnection line patterns of the first standard cell may be spaced apart from the first special boundary.

### CROSS-REFERENCE TO RELATED APPLICATION(S)

This application claims benefit of priority to Korean Patent Application No. 10-2021-0160269 filed on Nov. 19, 2021 in the Korean Intellectual Property Office, the disclosure of which is incorporated herein by reference in its entirety.

### BACKGROUND

The present disclosure relates to semiconductor devices.

Standard cells may be used to design a semiconductor device including an integrated circuit. Standard cells have a predetermined architecture and are stored in a cell library. When a semiconductor device is designed, standard cells are extracted from a cell library and disposed in appropriate locations on a layout of the semiconductor device. As described above, when a standard cell library for standard cells included in an integrated circuit of a semiconductor device is generated in a process of designing a semiconductor device and an integrated circuit is implemented using the generated standard cell library, time and costs required for design and implementation may be reduced.

### SUMMARY

Some example embodiments provide semiconductor devices having an improved degree of integration and improved reliability.

According to an example embodiment, a semiconductor device includes a standard cell including active patterns extending in a first direction, gate patterns intersecting the active patterns and extending in a second direction perpendicular to the first direction, and contact patterns being on the active patterns at opposite sides of the gate patterns, signal line patterns extending in the first direction on the standard cell, arranged in the second direction, and electrically connected to the standard cell, and a first power interconnection line pattern and a second power interconnection line pattern both extending in the first direction on the standard cell, the first power interconnection line pattern and the second power interconnection line pattern electrically connected to some of the active patterns and configured to supply different voltages, respectively, to the standard cell. The standard cell includes a first standard cell and a second standard cell, and the first standard cell and the second standard cell partially overlap each other to define a cell sharing region. The contact patterns include a sharing contact pattern that is in the cell sharing region and electrically connected to one of the first power interconnection line pattern and the second power interconnection line pattern. At least one of the signal line patterns electrically connected to a contact pattern that is closest to the sharing contact pattern among the contact patterns is spaced apart from the cell sharing region.

According to an example embodiment, a semiconductor device includes a standard cell including active patterns extending in a first direction, gate patterns extending in a second direction perpendicular to the first direction, and contact patterns being on the active patterns at opposite sides of the gate patterns, and interconnection line patterns extending in the first direction and spaced apart from each other in the second direction, on the stand cell. The standard cell includes a first standard cell and a second standard cell partially overlapping each other. A first special boundary is defined on a cell boundary of the second standard cell, in the first standard cell, and a second special boundary is defined on a cell boundary of the first standard cell, in the second standard cell. At least one of the interconnection line patterns of the first standard cell is spaced apart from the first special boundary.

According to an example embodiment, a semiconductor device includes a standard cell including active patterns extending in a first direction, gate patterns extending in a second direction perpendicular to the first direction, first contact patterns being on the active patterns at opposite sides of the gate patterns, and second contact patterns on the gate patterns, interconnection line patterns extending in the first direction on the standard cell and arranged in the second direction, and via patterns electrically connecting the first contact patterns and the interconnection line patterns to each other. The interconnection line patterns include a first power interconnection line pattern and a second power interconnection line pattern both extending in the first direction, and the first power interconnection line pattern and the second power interconnection line pattern are configured to supply different voltages, respectively to the standard cell, and are side by side with each other. The standard cell includes a first standard cell and a second standard cell, and the first standard cell and the second standard cell are between the first power interconnection line pattern and the second power interconnection line pattern and partially overlap each other to define a cell sharing region. The active patterns comprise a first active pattern in the first standard cell and a second active pattern in the second standard cell. The first contact patterns include a first sharing contact pattern on the first active pattern and a second sharing contact pattern on the second active pattern, in the cell sharing region. The via patterns include a first via pattern on the first sharing contact pattern and a second via pattern on the second sharing contact pattern in the cell sharing region. The first via pattern is in a region in which the first sharing contact pattern overlaps the first power interconnection line pattern, and the second via pattern is in a region in which the second sharing contact pattern overlaps the second power interconnection line pattern.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a flowchart illustrating a method of designing and fabricating a semiconductor device according to an example embodiment.

FIGS. 2A and 2B are block diagrams illustrating a method of designing a layout of a semiconductor device according to an example embodiment.

FIGS. 3A and 3B are diagrams each illustrating a method of designing a layout of a semiconductor device according to some example embodiments.

FIGS. 4A and 4B are diagrams each illustrating a method of designing a layout of a semiconductor device according to some example embodiments.

FIGS. 5A and 5B are diagrams each illustrating a circuit provided by a layout of a semiconductor device according to some example embodiments.

FIGS. 6A to 6C are diagrams each illustrating an operation of disposing rearranging interconnection line patterns when standard cells are disposed to overlap each other, in a layout of a semiconductor device according to some example embodiments.

FIGS. 7A and 7B are cross-sectional views of a semiconductor device according to an example embodiment.

FIG. 8 is a cross-sectional view of a semiconductor device according to an example embodiment.

FIG. 9A is a diagram illustrating a circuit provided by a layout of a semiconductor device according to an example embodiment.

FIG. 9B is a layout view of the semiconductor device of FIG. 9A according to example embodiments.

FIG. 10A is a diagram illustrating a circuit provided by a layout of a semiconductor device according to an example embodiment.

FIG. 10B is a layout view of the semiconductor device of FIG. 10A according to example embodiments.

FIG. 11A is a diagram illustrating a circuit provided by a layout of a semiconductor device according to an example embodiment.

FIG. 11B is a layout view of the semiconductor device of FIG. 11A according to an example embodiment.

FIG. 12 is a diagram illustrating a process in which standard cells disposed to overlap each other in a layout of a semiconductor device according to an example embodiment.

### DETAILED DESCRIPTION

Hereinafter, some example embodiments will be described with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “A, B, and C” mean either A, B, C or any combination thereof.

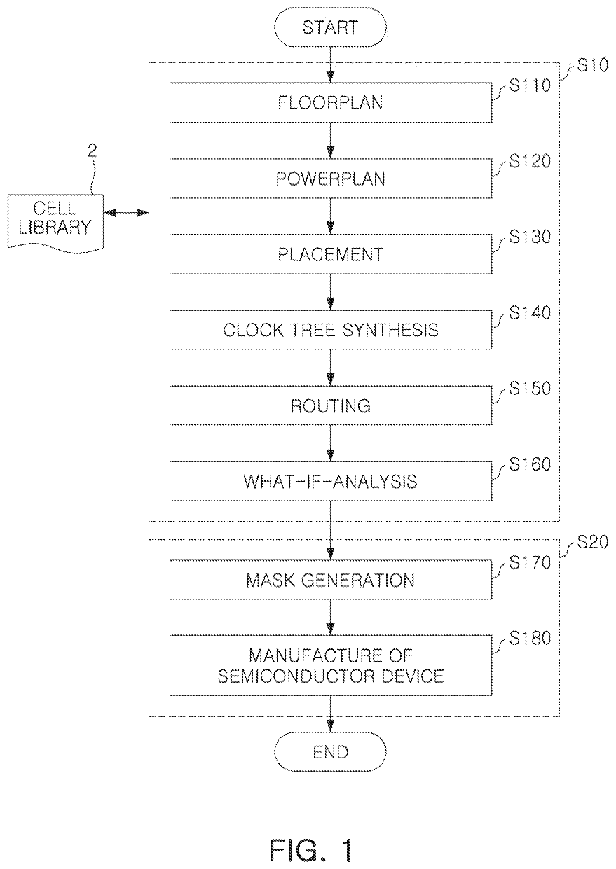

FIG. 1 is a flowchart illustrating a method of designing and fabricating a semiconductor device according to an example embodiment.

Referring to FIG. 1, a method of designing and fabricating a semiconductor device may include a designing operation S10 and a fabricating process operation S20. The designing operation S10 may be an operation of designing a layout for a circuit, and may be performed using a tool for designing a circuit. The tool may be a program including a plurality of instructions executed by a processor. Accordingly, the designing operation S10 may be a computer-implemented operation for designing a circuit. The fabricating process operation S20 may be an operation of fabricating a semiconductor device based on a designed layout (e.g., the circuit designed in the designing operation S10), and may be performed by a semiconductor process module.

The designing operation S10 may include a floorplan operation S110, a powerplan operation S120, a placement operation S130, a clock tree synthesis (CTS) operation S140, a routing operation S150, a staple line insertion operation S155, and a what-if-analysis operation S160. Among operations of the designing operation S10, a least some operations may be performed based on standard cells of a standard cell library 2.

The floorplan operation S110 may be an operation of designing cuts and movements for fabricating a logically designed schematic circuit. In the floorplan operation S110, memory or functional circuit blocks may be disposed. In the present operation, for example, functional circuit blocks that need to be disposed adjacent to each other may be identified, and a space for the functional circuit blocks may be assigned in consideration of available space and required performance. For example, the floorplan operation S110 may include an operation of generating a site-row and an operation of forming a routing track on the generated site-row. The site-row may be a frame for disposing standard cells stored in a cell library, based on a specified design rule. The metal routing track may provide an imaginary line on which interconnection are to be formed later. In the subsequent routing operation S150, interconnections may be disposed in the routing tracks.

The powerplan operation S120 may be an operation of disposing patterns of interconnections connecting local power, for example, a driving voltage or a ground, in the disposed functional circuit blocks. For example, patterns of the interconnections connecting power or grounds may be formed such that the power is uniformly supplied to an entire chip in the form of a net. For example, a pattern may be referred to as a power rail or a power supply line. The patterns may be formed in the form of a net according to various rules.

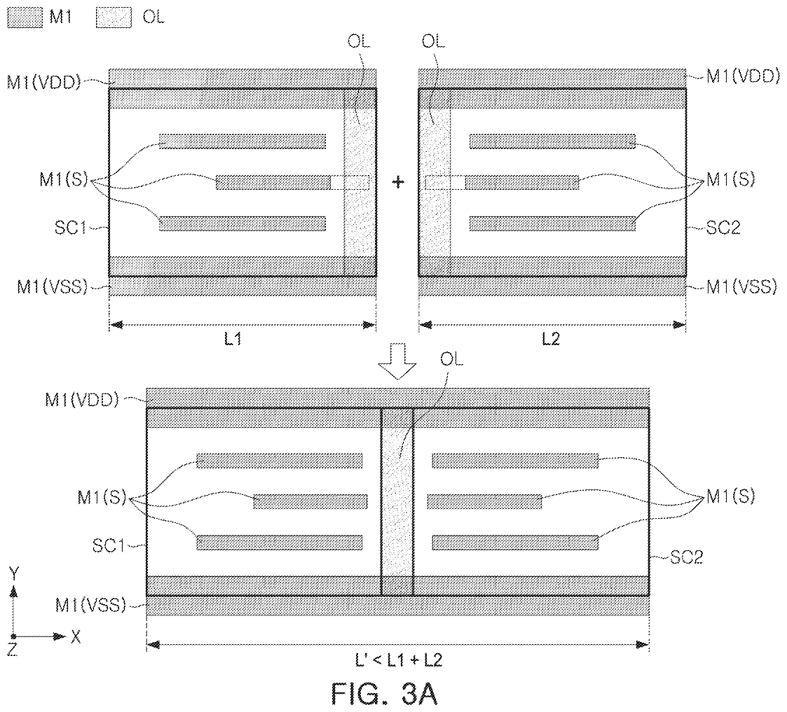

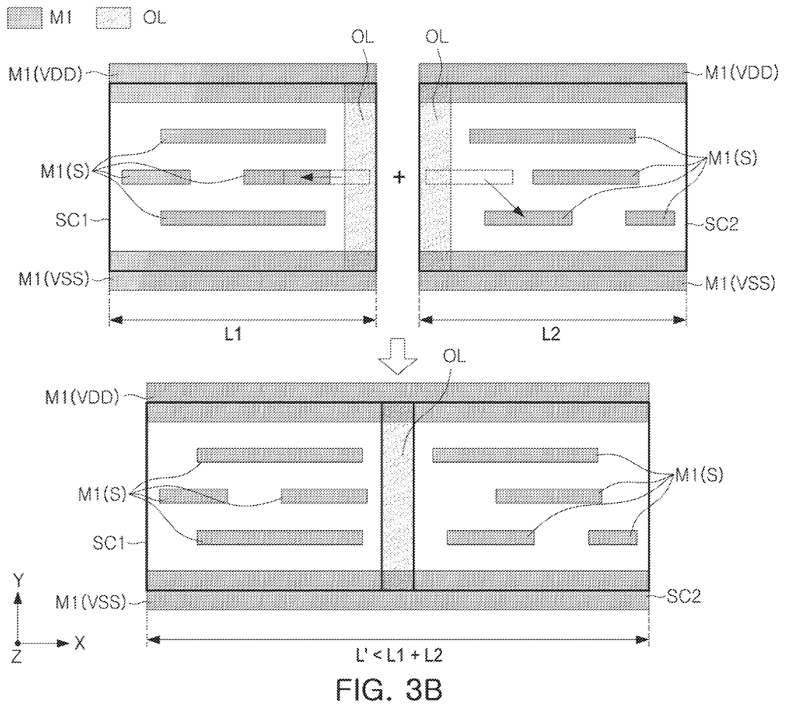

The placement operation S130 may be an operation of disposing patterns of elements constituting the functional circuit block, and may include an operation of disposing standard cells. In some example embodiments, a cell sharing region and a special boundary may be defined in the standard cells. In the present operation, adjacent standard cells may be disposed to overlap each other to share the cell sharing region and interconnection lines on a standard cell may be rearranged in consideration of the special boundary, which will be described later in greater detail with reference to FIGS. 3A and 3B. Empty regions may be formed between the standard cells disposed in the present operation. The empty regions may be filled with filler cells. Unlike standard cells including an operable semiconductor element and a unit circuit implemented by semiconductor elements, the filler cells may be dummy regions. By the present operation, a shape or a size of a pattern for configuring transistors and interconnections to be actually formed on a semiconductor substrate may be defined. For example, layout patterns such as a PMOS, an NMOS, an N-WELL, a gate electrode, and interconnections to be disposed thereon may be appropriately disposed to form an inverter circuit on an actual semiconductor substrate.

The CTS operation S140 may be an operation of forming patterns of signal lines of a center clock related to a response time determining performance of a semiconductor device.

The routing operation S150 may be an operation of forming an interconnection structure connecting disposed standard cells to each other. The interconnection structure may be electrically connected to interconnections in the standard cells and may electrically connect standard cells to each other.

The what-if-analysis operation S160 may be an operation of verifying and correcting the generated layout. Items to be verified may include design rule check (DRC) verifying whether a layout is generated to be appropriate to a design rule, electrical rule check (ERC) verifying whether the layout is appropriately generated without electrical disconnection therein, and/or layout vs schematic (LVS) checking whether the layout matches a gate-level net list.

The fabricating process operation S20 may include a mask manufacturing operation S170 and a fabricating operation S180 of the semiconductor device.

The mask manufacturing operation S170 may include an operation of performing optical proximity correction (OPC) on layout data generated in the designing operation S10 to generate mask data for forming various patterns on a plurality of layers and an operation of manufacturing a mask based on the mask data. The optical proximity correction (OPC) may be performed to correct a distortion which may occur in a photolithography process. The mask may be manufactured in a manner depicting layout patterns using a chromium thin film applied to a glass or quartz substrate.

In the fabricating operation S180, various types of exposure and etching processes may be repeatedly performed. Such processes may be repeatedly performed to sequentially form shapes of patterns configured when a layout is designed on a silicon substrate. For example, various semiconductor processes may be performed on a semiconductor substrate (e.g., a wafer) using a plurality of masks to fabricate a semiconductor device in which an integrated circuit is implemented. The semiconductor processes may include a deposition process, an etching process, an ion implantation process, a cleaning process, and the like. In addition, the semiconductor process may include a packaging process of mounting a semiconductor device on a printed circuit board (PCB) and encapsulating the mounted semiconductor device with an encapsulant, and/or a test process for the semiconductor device or the package.

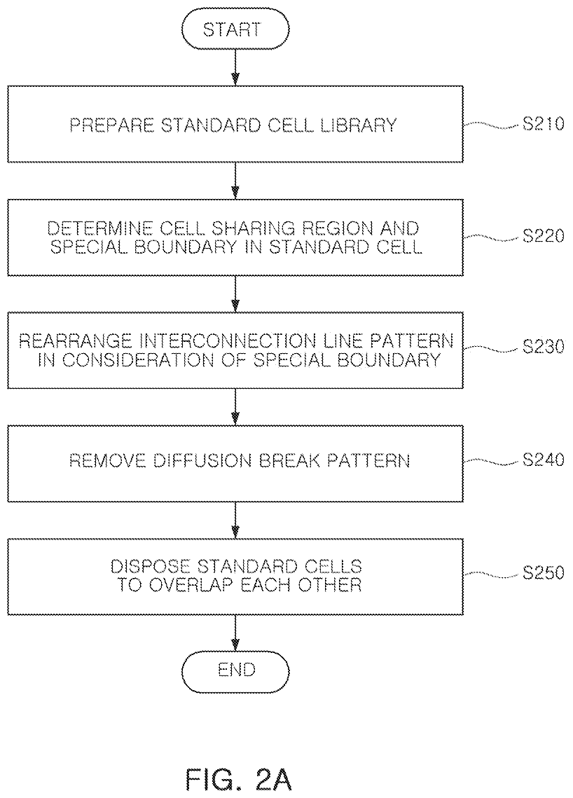

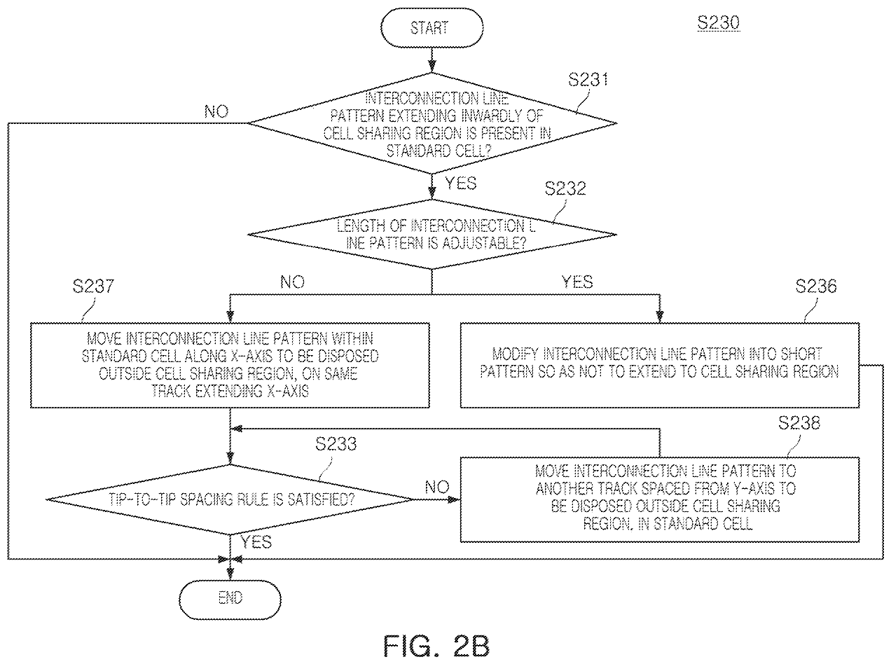

FIG. 2A is a block diagram illustrating a method of designing a layout of a semiconductor device according to an example embodiment.

Referring to FIG. 2A, the method of designing a layout of a semiconductor device may include operation S210 of preparing a standard cell library, operation S220 of determining a cell sharing region and a special boundary in a standard cell, operation S230 of rearranging interconnection line patterns in consideration of the cell sharing region and the special boundary, operation S240 of removing a diffusion break pattern, and operation 250 of disposing standard cells to overlap each other.

The operation S210 of preparing a standard cell library may be performed. A standard cell refers to a unit of an integrated circuit, in which a size of a layout meets a desired (or alternatively, predetermined) rule, having a desired (or alternatively, predetermined) function. The standard cell may include an input pin and an output pin and may process a signal received through the input pin and output a signal through the output pin. For example, the standard cell may correspond a basic cell such as an AND logic gate, an OR logic gate, a NOR logic gate, or an inverter, a complex cell such as an OR/AND/INVERTER (OAI) or an AND/OR/INVERTER (AOI), a multiplexer (MUX), or a half-adder (ADDH), or a storage element (e.g., a master-slave flip-flop or a latch).

The standard cell library may include information on standard cells. For example, the standard cell library may include a name of a standard cell, information on functions, timing information, power information, and layout information. The standard cell library may be stored in a storage such as a storage device, and the standard cell library may be provided by accessing the storage.

The operation S220 of determining a cell sharing region and a special boundary in a standard cell may be performed. Determining the cell sharing region may include determining a region, in which standard cells are to overlap each other, in each standard cell for the operation S250 of disposing the standard cells to overlap each other. The cell sharing region may be a power sharing region allowing a power supply voltage and a ground voltage to be applied to standard cells sharing the cell sharing region. In this case, the transistors of each of the standard cells sharing the cell sharing region may share an active pattern and a contact pattern in the cell sharing region.

Determining the special boundary may be performed from a cell boundary of another standard cell present in a single standard cell when standard cells are disposed to overlap each other by the cell sharing region. The special boundary may be determined in relation to the cell sharing region. The cell sharing region may correspond to a region between special boundaries, and may be defined as a region between a cell boundary of one standard cell and a cell boundary of another standard cell, a portion of which overlaps the one standard cell. For example, the special boundary may be defined as a cell boundary of a second standard cell overlapping a first standard cell and a cell boundary of the first standard cell overlapping the second standard cell when a portion of the first standard cell overlaps the second standard cell.

The operation S230 of rearranging interconnection line patterns in consideration of the cell sharing region and the special boundary may be performed. The interconnection line patterns are desired to be designed while satisfying a design rule. The design rule may include a tip-to-tip spacing rule for arranging interconnection line patterns in a layout such that a distance between adjacent end portions of the interconnection line patterns is greater than or equal to a desired or critical separation distance. The critical separation distance may refer to a minimum distance at patterns of a layout that are actually transferred to or patterned on a substrate during a semiconductor manufacturing process to physically separate layers formed in a semiconductor device. In the case in which the standard cells overlap each other, a distance between the interconnection line patterns may be reduced, as compared with a case in which standard cells do not overlap each other. When there is an interconnection line pattern passing through the special boundary and then extending inwardly of the cell sharing region, violation of a design rule may occur in relation to other adjacent interconnection line patterns. The present operation may be an operation of rearranging the interconnection line patterns such that a design rule between the interconnection line patterns may be satisfied when the standard cells are disposed to overlap each other. A method of rearranging interconnection line patterns to design a layout will be further described later with reference to FIGS. 2B, 3A, and 3B.

The operation S240 of removing a diffusion break pattern may be performed. Although a diffusion break pattern is present on a cell boundary between the existing standard cells, transistors of the standard cells share an active pattern in the cell sharing region, and thus the diffusion break pattern should be removed. Accordingly, before the standard cells are disposed to overlap each other, the diffusion break pattern may be removed in the layout of the standard cells. The diffusion break pattern may correspond to a dummy gate pattern.

The operation 250 of disposing standard cells to overlap each other may be performed. The operation 250 of disposing standard cells to overlap each other may be included in the operation S130 described above with reference to FIG. 1. In the present operation, among adjacent standard cells, the cell sharing region may be shared between standard cells.

FIG. 2B is a block diagram illustrating a method of designing a layout of a semiconductor device according to an example embodiment.

FIGS. 3A and 3B are diagrams illustrating a method of designing a layout of a semiconductor device according to some example embodiments. In FIGS. 3A and 3B, a cell boundary of a standard cell, power interconnection line patterns M1(VDD), M1(VSS), and the interconnection line patterns M1(S) are illustrated, and other patterns of a layout are not illustrated. The power interconnection line patterns M1 (VDD) and Ml(VSS) may supply different potentials to a standard cell SC1 or SC2 disposed therebetween. For example, the first power interconnection line pattern M1(VDD) may supply a first voltage VDD to the first and second standard cells SC1 and SC2, and the second power interconnection line pattern M1(VSS)) may supply a second voltage VSS to the first and second standard cells SC1 and SC2. The first voltage VDD may be higher than the second voltage VSS. The interconnection line patterns M1(S) may be electrically connected to the standard cells SC1 and SC2.

Referring to FIGS. 2B to 3B, an example placement method in the case, in which standard cells include a first standard cell SC1 and a second standard cell SC2 disposed to be adjacent to each other, will be described in detail. The operation S230 of rearranging interconnection line patterns may include operation S231 of determining whether an interconnection line pattern M1(S) extending into a cell sharing region OL is present in the standard cells SC1 and SC2.

The operation S230 of rearranging the interconnection line patterns M1(S) may include operation S232 of, when an interconnection line pattern M1(S) extending into the cell sharing region OL is present, determining whether a length of the interconnection line pattern M1(S) may be adjusted. Determining a length of an interconnection line pattern may include determining whether a minimum area rule, which is a type of design rule, is satisfied when a length of an interconnection line is decreased. For example, when the interconnection line pattern M1(S) does not satisfy the minimum area rule, a design margin for routing interconnections may not be secured.

In operation S236, when the length of the interconnection line pattern M1(S) is determined to be adjustable, the interconnection line pattern M1(S) may be modified into a short pattern, as illustrated in FIG. 3A. Then, when the operation S250 of disposing the standard cells SC to overlap each other is performed, a critical separation distance between adjacent interconnection line patterns M1(S) may be sufficiently secured between the first standard cell SC1 and the second standard cell SC2, as compared with a case in which the length of the interconnection line pattern M1(S) is not adjusted.

In operation S237, when the length of the interconnection line pattern M1(S) is determined not to be adjustable, the interconnection line pattern may be moved within a standard cell along an X-axis to be disposed outside the cell sharing region OL, on the same track extending in an X-direction, as illustrated in FIG. 3B. The track may be a routing track extending in the X-direction. In operation S233, when the interconnection line pattern M1(S) is moved along the X-axis, a determination may be made as to whether the interconnection line pattern M1(S) satisfies a tip-to-tip spacing rule on the same track with another interconnection line pattern M1(S).

When the tip-to-tip spacing rule is satisfied, the rearrangement of the interconnection line pattern M1(S) may be terminated. In operation S238, when the tip-to-tip spacing rule is not satisfied, the interconnection line pattern M1(S) in the standard cell may be moved to another track spaced along a Y-axis, instead of further moving the interconnection line pattern M1(S) along the X-axis in the same track, to be disposed outside the cell sharing region OL. When the interconnection line pattern M1(S) is moved to another track, a determination may be made again as to whether the interconnection line pattern M1(S) satisfies the tip-to-tip spacing rule with another interconnection line pattern M1(S).

In FIG. 3B, when the interconnection line pattern M1(S) of the first standard cell SC1 is moved along the X-axis on the same track, it does not violate the tip-to-tip spacing rule with another interconnection line pattern M1(S). In FIG. 3B, when an interconnection line pattern M1(S) of the second standard cell SC2 is moved along the X-axis on the same track, it may not satisfy the tip-to-tip spacing rule with another interconnection line pattern M1(S), the interconnection line pattern M1(S) may be moved to another track along the Y-axis, to be disposed outside the cell sharing region OL.

The interconnection line pattern M1(S) may be arranged to design a layout such that a tip-to-tip spacing rule between interconnection line patterns M1(S) is not violated even when standard cells SC are disposed to partially overlap each other. Thus, reliability of the semiconductor device may be improved. In addition, when the first standard cell SC1 has a length L1 in the X-direction and the second standard cell SC2 has a length L2 in the X-direction, the first and second standard cells SC1 and SC2 may be disposed to partially overlap each other. In this case, a length L′ of a region, in which the first and second standard cells SC1 and SC2 are disposed, in the X-direction may be less than a sum of the lengths L1 and L2. For example, waste of a space between adjacent standard cells SC1 and SC2 may be significantly reduced to improve a degree of integration of the semiconductor device. On the other hand, not only two adjacent standard cells SC1 and SC2 but also a plurality of standard cells arranged in the X-direction may be disposed to partially overlap each other, so that the degree of integration of the semiconductor device may be further improved.

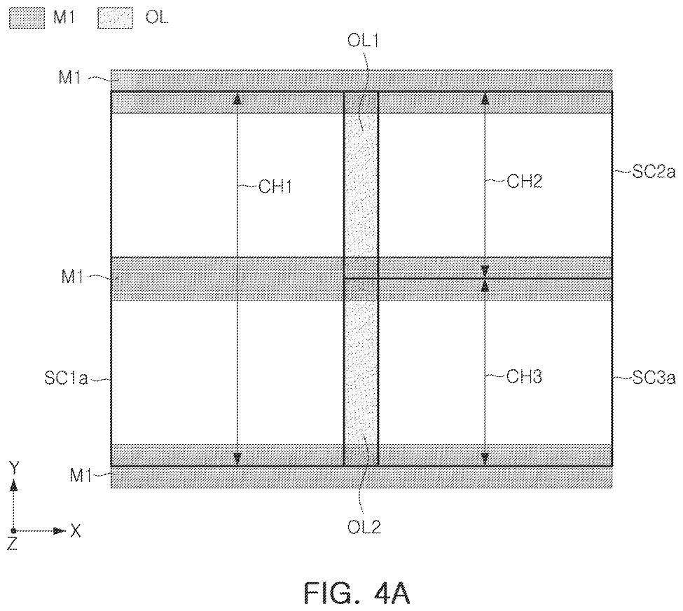

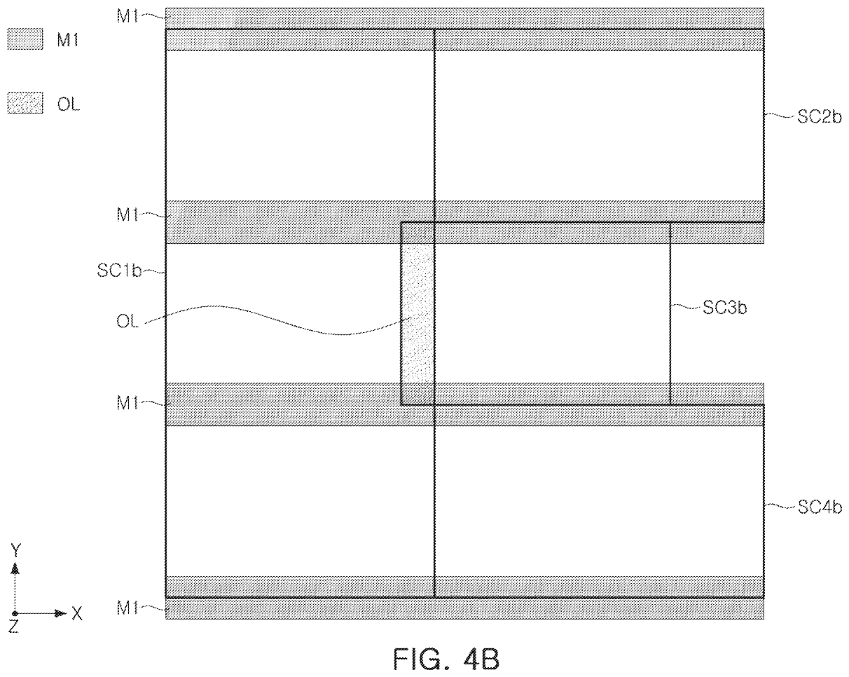

FIGS. 4A and 4B are diagrams each illustrating a method of designing a layout of a semiconductor device according to some example embodiments.

Referring to FIGS. 4A and 4B, even when standard cells SC having different cell heights, among the adjacent standard cells SC, are disposed to overlap each other, interconnection line patterns may be rearranged in the same manner as described in the operations of FIG. 2B. Here, the term “height” (for example, “cell height”) used in relation to the standard cell may refer to a length or a distance of a standard cell in a Y-direction, in a plan view.

Referring to FIG. 4A, a second standard cell SC2a and a third standard cell SC3a adjacent to one side of a first standard cell SC1a may overlap the first standard cell SC1a, and the first to third standard cells SC1a, SC2a, and SC3a may have different cell heights. For example, a cell height CH1 of the first standard cell SC1a may be the same as a sum of a cell height CH2 of the second standard cell SC2a and a cell height CH3 of the third standard cell SC3a. The first standard cell SC1a may share a first cell sharing region OL1 with the second standard cell SC2a, and existing interconnection line patterns partially extending into the first cell sharing region OL1 may be rearranged to an outside of the first sharing region OL1. Likewise, the first standard cell SC1a may share a second cell sharing region OL2 with the third standard cell SC3a, and existing interconnection line patterns partially extending into the second cell shared region OL2 may be rearranged or move to an outside of the cell sharing region OL2.

Referring to FIG. 4B, a first standard cell SC1b may have a cell height, greater than a cell height of each of second to fourth standard cells SC2b, SC3b, and SC4b, and the first standard cell SC1b may overlap at least one standard cell, among a plurality of standard cells adjacent to one side of the first standard cell SC1b, for example, second to fourth standard cells SC2b, SC3b, and SC4b. As described above, some of standard cells adjacent to each other may overlap each other, and others of standard cells adjacent to each other may be disposed so as not to overlap each other. The first standard cell SC1b may share a cell sharing region OL with the third standard cell SC3b, and existing interconnection line patterns partially extending into the cell sharing region OL may be rearranged to an outside of the cell sharing region OL.

Hereinafter, a method of designing a semiconductor device will be described using a method of designing a layout by rearranging interconnection line patterns to partially overlap a first standard cell SC1 and a second standard cell SC2 that correspond to layouts of specific circuits, as an example. The disclosed layouts of the specific circuits are provided to describe some examples, and example embodiments are not limited to the types of the specific circuits disclosed herein.

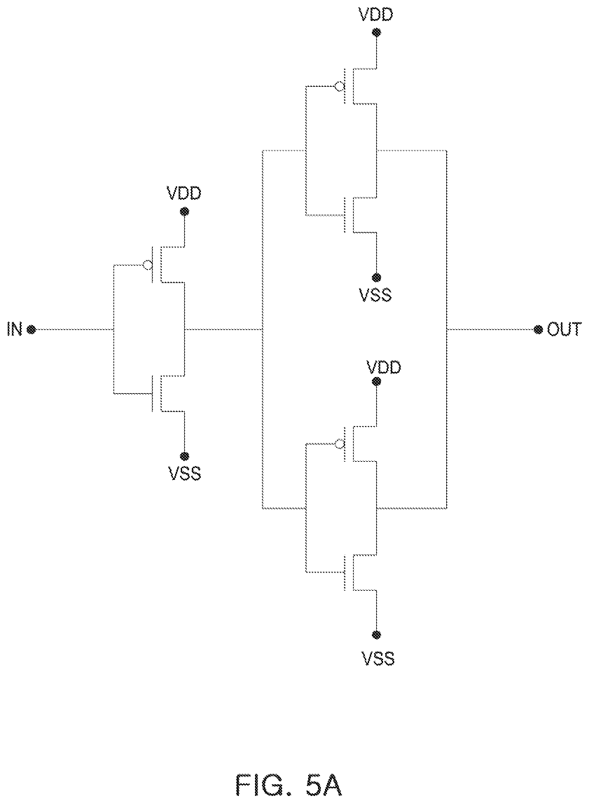

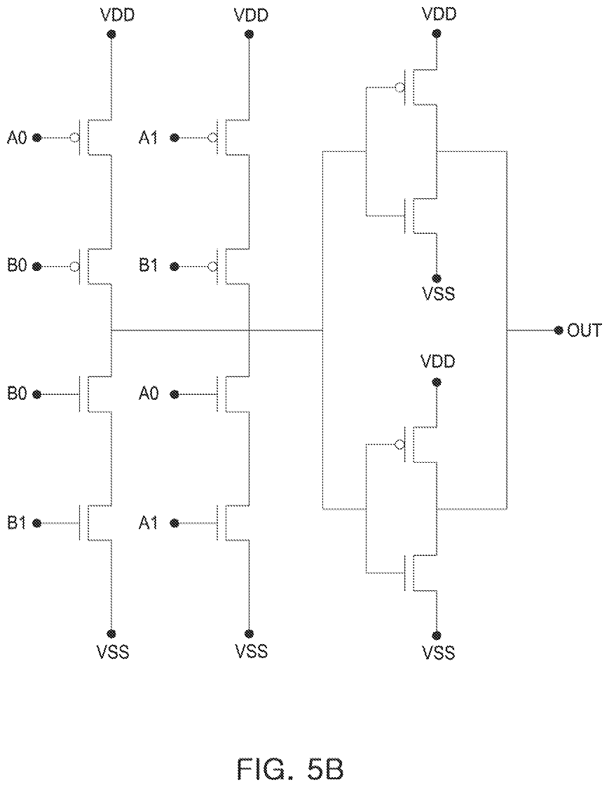

FIGS. 5A and 5B are diagrams each illustrating a circuit provided by a layout of a semiconductor device according to some example embodiments.

FIG. 5A illustrates a buffer circuit, and FIG. 5B illustrates an AND/OR/INVERTER (AOI) circuit.

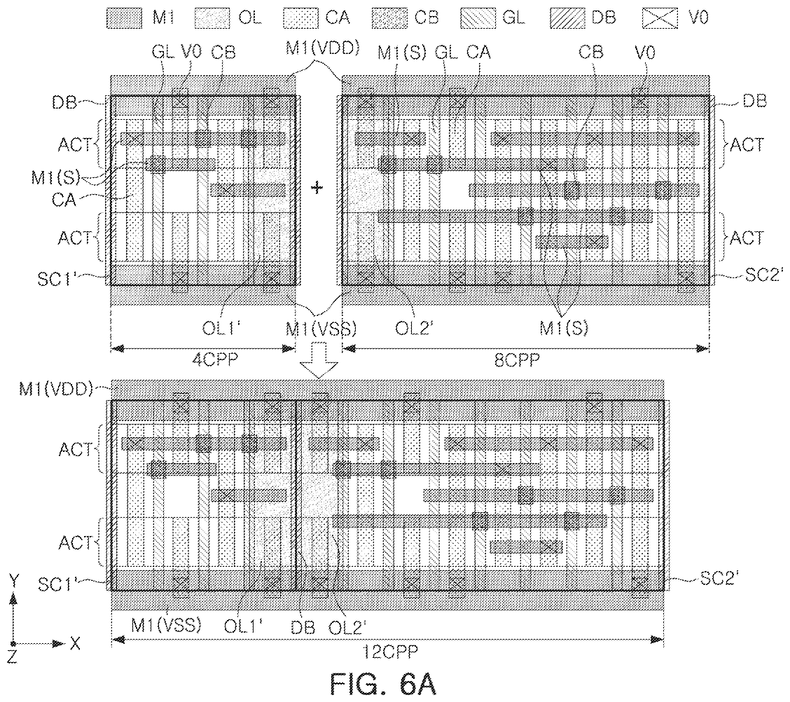

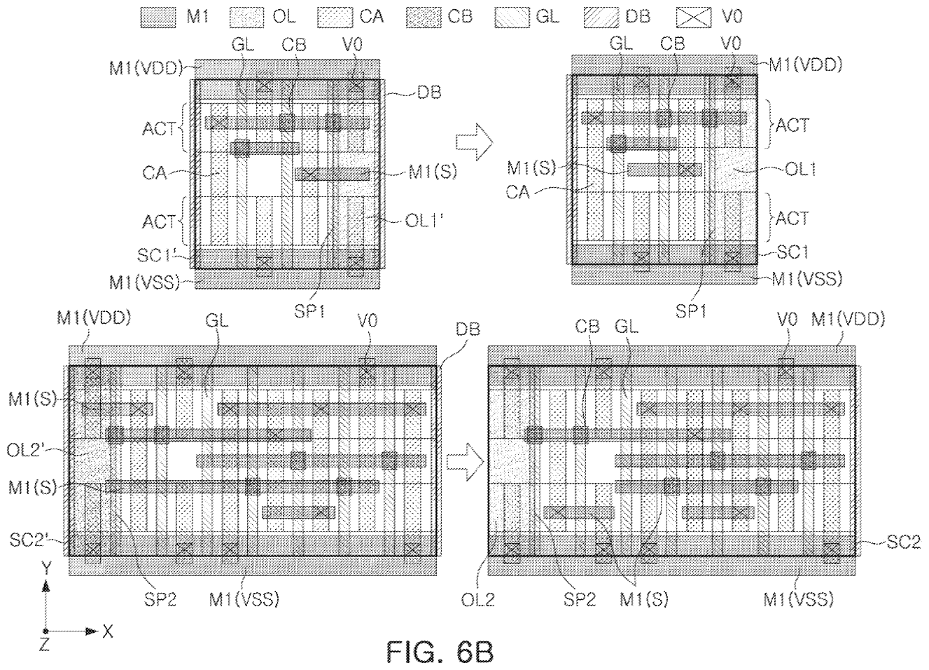

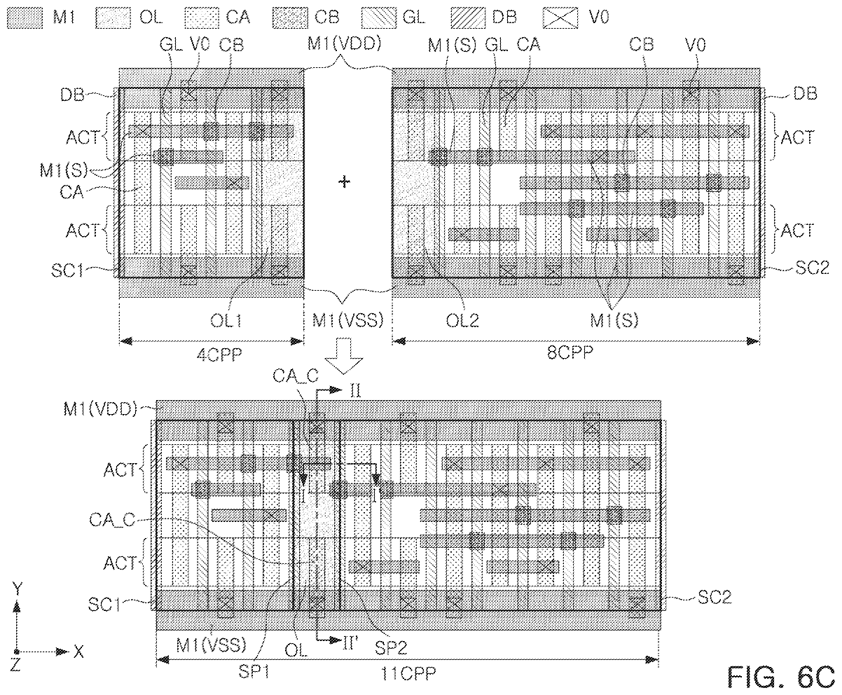

FIGS. 6A to 6C are diagrams each illustrating an operation of disposing rearranging interconnection line patterns when standard cells are disposed to overlap each other, in a layout of a semiconductor device according to some example embodiments.

A semiconductor device may include a layout including active patterns (ACT), gate patterns GL intersecting the active patterns ACT, contact patterns CA disposed on the active patterns ACT on opposite sides of the gate patterns GL, gate contact patterns CB on the gate patterns GL, via patterns V0 on the contact patterns CA, power interconnection line patterns M1(VDD) and M1 (VSS), and interconnection line patterns (M1(S). In the drawings, the standard cell SC may be illustrated as including the active patterns ACT, the gate patterns GL, and the contact patterns CA disposed inside a cell boundary (a rectangle indicated by bold lines), and the via patterns V0, the power interconnection line patterns M1(VDD) and M1(VSS), and the interconnection line patterns M1(S) may be illustrated as being disposed on the standard cell SC.

As an example, the semiconductor device may include a layout of first standard cells SC1′ and SC1, corresponding to the buffer circuit of FIG. 5A, and a layout of second standard cells SC2′ and SC2 corresponding to the AOI circuit of FIG. 5B.

Although not illustrated, in each of the standard cells SC1′, SC1, SC2′, and SC2, well regions such as N-well regions may be defined and a pair of active patterns ACT extending in an X-direction and a plurality of gate patterns GL extending in a Y-direction may be disposed. Each of the power interconnection line patterns M1(VDD) and M1(VSS) may be disposed to extend along cell boundaries (represented by relatively bold lines in the drawings) in an X-direction of each of the standard cells SC1′, SC1, SC2′, and SC2. Hereinafter, a process of rearranging interconnection line patterns M1(S) when standard cells are disposed to overlap each other will be described.

FIG. 6A illustrates a comparative example in which the first standard cell SC1′ and the second standard cell SC2′ are disposed without overlapping each other. In the placement operation S130 of FIG. 1, the first standard cell SC1′ and the second standard cell SC2′ may be disposed so as not to overlap each other. In the comparative example, the first standard cell SC1′ and the second standard cell SC2′ adjacent to each other in an X-direction may be disposed such that cell boundaries extending in a Y-direction be in contact with each other. Adjacent regions OL1′ and OL2′ of the first standard cell SC1′ and the second standard cell SC2′ may not overlap each other.

Referring to FIG. 6B, the operation S230 of rearranging the interconnection line patterns of FIGS. 2A and 2B may be performed to newly design the layout of the first standard cell SC1′ and the layout of the second standard cell SC2′. This is because it may be difficult to satisfy the design rule of the interconnection line patterns M1(S) when the adjacent regions OL1′ and OL2′ of FIG. 6A simply overlap each other without rearranging the interconnection line patterns.

In the first standard cell SC1′, when a cell sharing region OL1 and a special boundary SP1 are determined, an interconnection line pattern M1(S) extending into the cell sharing region OL1 may be present. In this case, the interconnection line pattern M1(S) desired to be rearranged may be an interconnection line pattern electrically connected to the contact pattern CA rather than an interconnection line pattern electrically connected to the gate contact pattern CB. However, example embodiments are not limited thereto. When a length of the interconnection line pattern M1(S) desired to be rearranged in the first standard cell SC1′ is decreased, a minimum area rule may not be satisfied. Therefore, the length of the interconnection line pattern M1(S) desired to be rearranged may not be adjusted. Accordingly, the interconnection line pattern M1(S) desired to be rearranged may be moved in the same track along an X-axis. In this case, because other interconnection line patterns M1(S) are absent on the same track, a design rule may be satisfied without a need to review a tip-to-tip spacing rule. Accordingly, as a result of rearranging the interconnection line pattern M1(S) extending into the cell sharing region OL1 from the first standard cell SC1′, the first standard cell SC1 may be newly designed. A diffusion break pattern DB present on the cell boundary of the first standard cell SC1′ may be removed.

In the second standard cell SC2′, when a cell sharing region OL2 and a special boundary SP2 are determined, an interconnection line pattern M1(S) extending into the cell sharing region OL2 may be present. In this case, the interconnection line pattern M1(S) desired to be rearranged may be an interconnection line pattern electrically connected to the contact pattern CA rather than an interconnection line pattern electrically connected to the gate contact pattern CB. However, example embodiments are not limited thereto. One of the interconnection line patterns M1(S) desired to be rearranged may satisfy a minimum area rule when a length thereof is decreased. Thus, the length of the interconnection line pattern may be adjusted to be short. Another interconnection line pattern M1(S) desired to be rearranged may not satisfy the minimum area rule when a length thereof is decrease. Thus, the length of the other interconnection line pattern may not be adjusted. Therefore, moving the another interconnection line pattern M1(S) in the same track along the X-axis may be taken into consideration. If still another interconnection line pattern M1(S) is present on the same track, however, the tip-to-tip spacing rule may not be satisfied by moving the another interconnection line pattern M1(S) in the same track along the X-axis. In this case, the interconnection line pattern M1(S) may be moved to another track spaced along the Y-axis to be disposed outside the cell sharing region OL2. Accordingly, as a result of rearranging the interconnection line patterns M1(S) extending into the cell sharing region OL2 in the second standard cell SC2′, the second standard cell SC2 may be newly designed. A diffusion break pattern DB, present on a cell boundary of the second standard cell SC2′ may be removed.

Referring to FIG. 6C, the first standard cell SC1 and the second standard cell SC2 may be disposed to overlap each other. A cell sharing region OL1 of the first standard cell SC1 and the cell sharing region OL2 of the second standard cell SC2 may fully overlap each other. In this case, the diffusion break pattern DB may not be disposed in the cell sharing region OL. A cell boundary of the first standard cell SC1 may be disposed within the second standard cell SC2 to be disposed on a special boundary SP2 of the second standard cell SC2, and a cell boundary of the second standard cell SC2 may be disposed within the first standard cell SC1 to be disposed on a special boundary SP1 of the first standard cell SC1.

The first standard cell SC1 may have a first cell boundary disposed in the second standard cell SC2 and extending in the Y-direction, and the second standard cell SC2 may have a second cell boundary disposed in the first standard cell SC1 and extending in the Y-direction. The cell sharing region OL may be defined between a first cell boundary and a second cell boundary. A distance between the first cell boundary and the second cell boundary in the X-direction may be the same as or substantially similar to a single pitch between the gate patterns GL. The interconnection line pattern M1(S), disposed in the first standard cell SC1, may be disposed to be closer to the second cell boundary than to the first cell boundary. The interconnection line pattern M1(S), disposed in the second standard cell SC2, may be disposed to be closer to the first cell boundary than to the second cell boundary. The second cell boundary may correspond to the special boundary SP1 of the first standard cell SC1, and may overlap the gate pattern GL of the first standard cell SC1. The first cell boundary may correspond to the special boundary SP2 of the second standard cell SC2, and may overlap the gate pattern GL of the second standard cell SC2.

A sharing contact pattern CA_C electrically connected to one of the first power interconnection line pattern M1(VDD) and the second power interconnection line pattern M1(VSS) may be disposed in the cell sharing region OL. The interconnection line pattern M1(S) electrically connected to the contact pattern CA closest to the sharing contact pattern CA_C may be spaced apart from the cell sharing region OL. The sharing contact pattern CA_C may simultaneously provide a power supply voltage or a ground voltage to both the first standard cell SC1 and the second standard cell SC2. The sharing contact pattern CA_C may be provided as a single pattern or a plurality of patterns. For example, the sharing contact pattern CA_C may include a first sharing contact pattern CA_C on a first active pattern ACT and a second sharing contact pattern CA_C on a second active pattern ACT. A single sharing contact pattern CA_C or a plurality of sharing contact patterns CA_C may be disposed in the cell sharing region OL (e.g., a power source sharing region) to supply a power source to the first standard cell SC1 and the second standard cell SC2. A first via pattern V0 may be disposed in a region, in which the first sharing contact pattern CA_C overlaps the first power interconnection line pattern M1(VDD), and a second via pattern VO may be disposed in a region in which the second sharing contact pattern (CA_C) overlaps the second power interconnection line pattern M1(VSS).

For example, when one contacted poly pitch (CCP) corresponds to a pitch of the gate structure GS in the X-direction, the first standard cells SC1 and SC1′ may have a width of four CPPs and the second standard cells SC2 and SC2′ may have a width of 8 CPPs. In the case of FIG. 6A, the standard cells SC1′ and SC2′ may be arranged to have a total width of 12 CPPs, but in the case of FIG. 6C, the standard cells SC1 and SC2 may be arranged to have a total width of 11 CPPs. Therefore, it can be seen that in the case in which the standard cells SC1 and SC2 are disposed so as to overlap each other, an arrangement area may be reduced as compared with the case in which they are disposed so as not to overlap each other.

As illustrated in FIG. 6A, the first and second standard cells SC1′ and SC2′ may be disposed to be in contact with each other. In this case, when adjacent regions OL1′ and OL2′ are respective power supply regions of the first and second standard cells SC1′ and SC2′, one of the two regions OL1′ and OL2′ may supply power even if the other of the two regions OL1′ and OL2′ is removed. Thus, one of the two standard cells SC1′ and SC2′ may normally operate. On the other hand, as illustrated in FIG. 6B, when the first and second standard cells SC1 and SC2 are disposed to partially overlap each other, the cell sharing region OL corresponds to a power supply region of each of the first and second standard cells SC1 and SC2. Therefore, when the cell sharing region OL is removed, both of the two standard cells SC1 and SC2 become inoperable. Such a manner may be used to check whether standard cells are disposed to overlap each other.

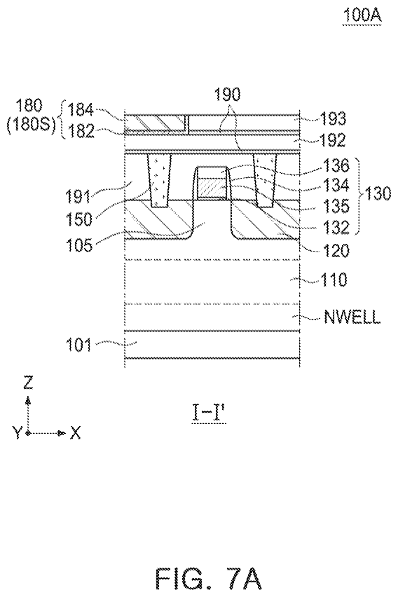

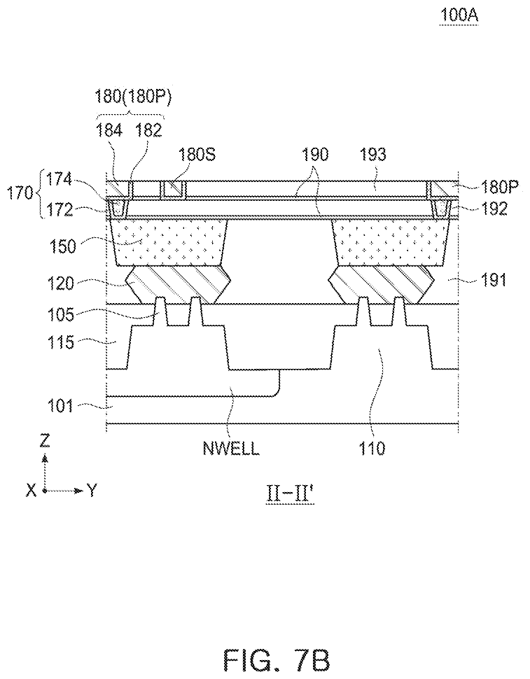

FIGS. 7A and 7B are cross-sectional views of a semiconductor device according to an example embodiment. FIG. 7A illustrates a cross-section of the semiconductor device taken along line I-I′ of FIG. 6C, and FIG. 7B illustrates a cross-section of the semiconductor device taken along line II-II′ of FIG. 6C.

A semiconductor device 100A may include a substrate 101, an active region 110 including active fins 105 on the substrate 101, a gate structure 130 extending to intersect the active region 110, source/drain regions 120 disposed on the active fin 105 of the active region 110 on both sides of the gate structure 130, a contact structure 150 connected to the source/drain regions 120, a via 170 on the contact structure 150, and interconnection layers 180. The semiconductor device 100A may further include a device isolation layer 115 defining the active region 110, interlayer insulating layers 191, 192, and 193, and etch-stop layers 190. The interconnection layers 180 may include a power interconnection layer 180P applying a power supply voltage/a ground voltage to a circuit of the semiconductor device 100A, and a signal interconnection layer 180S applying a signal to the circuit of the semiconductor device 100A.

The active region 110 may correspond to the active pattern ACT of a layout, the gate structure 130 may correspond to the gate pattern GL of the layout, and the contact structure 150 may correspond to the contact pattern CA of the layout. A power interconnection layer 180P may correspond to power interconnection line patterns M1(VDD) and M1(VSS) of the layout, and a signal interconnection layer 180S may correspond to the interconnection line patterns M1(S).

The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like. The substrate 101 may include doped regions such as an N-well region NWELL.

The device isolation layer 115 may define active regions ACT in the substrate 101. The device isolation layer 110 may be formed by, for example, a shallow trench isolation (STI) process. As illustrated in FIG. 7A, the device isolation layer 115 may include a region extending to a greater depth downwardly into the substrate 101 between adjacent active regions 110, but example embodiments are not limited thereto. According to some example embodiments, the device isolation layer 115 may have a curved upper surface having a level increased in a direction toward the active fins 105 (e.g., a concave upper surface). The device isolation layer 115 may be formed of an insulating material and may include, for example, an oxide, a nitride, or a combination thereof.

The active regions 110 may be defined by the device isolation layer 110 in the substrate 101 and may be disposed to extend in an X-direction. The active regions 110 may provide FinFET devices (e.g., transistors including active fins 105 having a fin structure). The active fins 105 may have a shape protruding from the substrate 101. Upper ends of the active fins 105 may be disposed to protrude from the upper surface of the device isolation layer 110 to a desired (or alternatively, predetermined) height. The active fins 105 may be provided as a portion of the substrate 101, or may include an epitaxial layer grown from the substrate 101. A portion of the active fins 105 may be recessed on opposite sides of the gate structures 130, and source/drain regions 120 may be disposed on the recessed active fins 105. According to example embodiments, the active regions 110 may have doped regions including impurities. For example, the active fins 105 may include impurities diffused from the source/drain regions 120 in a region in contact with the source/drain regions 120. In example embodiments, the active fins 105 may be omitted. In this case, the active regions 110 may have a planar upper surface.

The source/drain regions 120 may be disposed on the active fin 105 of the active region 110 on at least one side of the gate structure 130. The source/drain regions 120 may serve as a source region or a drain region of a transistor. The source/drain regions 120 may have a merged shape in which they are connected to each other between the active fins 105 adjacent in the Y-direction, as illustrated in FIG. 7A. However, example embodiments are not limited thereto. The source/drain regions 120 may have angular side surfaces in a cross-section in the Y-direction of FIG. 7A. However, in example embodiments, the source/drain regions 120 may have various shapes, for example, one of polygonal, circular, elliptical, and rectangular shapes.

The source/drain regions 120 may be formed of a semiconductor material. For example, the source/drain regions 120 may include at least one of silicon (Si), silicon germanium (SiGe), silicon arsenic (SiAs), silicon phosphide (SiP), and silicon carbide (SiC). For example, the source/drain regions 120 may include N-type doped silicon (Si) and/or P-type doped silicon germanium (SiGe). In some example embodiments, the source/drain regions 120 may include a plurality of regions including elements having different concentrations and/or doping elements.

The gate structures 130 may be disposed on the active regions 110 to intersect the active fins 105 and to extend in one direction, for example, the Y-direction. Channel regions of transistors may be formed in the active fins 105 intersecting the gate structures 130. The gate structure 130 may include a gate insulating layer 132, a gate electrode layer 135, gate spacer layers 134, and a gate capping layer 136.

The gate insulating layer 132 may be disposed between the active fin 105 and the gate electrode layer 135. In some example embodiments, the gate insulating layer 132 may include a plurality of layers or may be disposed to extend upwardly along a side surface of the gate electrode layer 135. The gate insulating layer 132 may include an oxide, a nitride, or a high-k dielectric material. The high-k dielectric material may refer to a dielectric material having a dielectric constant, higher than that of a silicon oxide (SiO₂) layer.

The gate electrode layer 135 may include a conductive material, for example, at least one of W, Ti, Ta, Mo, TiN, TaN, WN, TiON, TiAlC, TiAlN, and TaAlC. The gate electrode layer 135 may include a semiconductor material such as doped polysilicon. The gate electrode layer 135 may include two or more multiple layers. The gate electrode layers 135 may be separated from each other in the Y-direction between at least some adjacent transistors, depending on a circuit configuration of the semiconductor device 100A. For example, the gate electrode layer 135 may be separated by an additional gate separation layer.

The gate spacer layers 134 may be disposed on opposite sides of the gate electrode layer 135. The gate spacer layers 134 may insulate the source/drain regions 120 from the gate electrode layer 135. The gate spacer layers 134 may have a multi-layer structure according to some example embodiments. The gate spacer layers 134 may be formed of a silicon oxide, a silicon nitride, or a silicon oxynitride, and, in particular, a low-k dielectric material. The gate spacer layers 134 may include, for example, at least one of SiO, SiN, SiCN, SiOC, SiON, and SiOCN.

The gate capping layer 136 may be disposed on an upper surface of the gate electrode layer 135, and the lower surface and side surfaces of the gate capping layer 136 may be surrounded by the gate electrode layer 135 and the gate spacer layers 134, respectively. The gate capping layer 134 may be formed of, for example, a silicon oxide, a silicon nitride, a silicon oxynitride, or combinations thereof.

The contact structure 150 may be connected to the source/drain regions 120 to apply an electrical signal or supply power to the source/drain regions 120. The contact structure 150 may extend from an upper portion to a lower portion to be in contact with the source/drain regions 120. The contact structure 150 may be disposed to recess a portion of the source/drain regions 120. The contact structure 150 may be disposed to be elongated in the Y-direction. For example, the contact structure 150 may have a line shape or a bar shape having a length greater in the Y-direction than in the X-direction. The contact structure 150 may have an inclined side surface of which a lower width is narrower than an upper width depending on an aspect ratio, but example embodiments are not limited thereto. The contact structure 150 may include at least one of, for example, titanium nitride (TiN), tantalum nitride (TaN), tungsten nitride (WN), tungsten carbon nitride (WCN), titanium (Ti), tantalum (Ta), tungsten (W), copper (Cu), aluminum (Al), cobalt (Co), ruthenium (Ru), and molybdenum (Mo). A metal-semiconductor compound layer, such as metal silicide, metal germanide, or metal silicide-germanide, may be further disposed between the contact structure 150 and the source/drain regions 120.

Although not illustrated, a gate contact structure may be further disposed on the gate electrode layer 135. The gate contact structure may correspond to the gate contact pattern CB of the layout. The gate contact structure may apply an electrical signal to the gate electrode layer 135.

The via 170 may be disposed on the contact structure 150 and may be connected to the interconnection layers 180. The via 170 may penetrate through the second interlayer insulating layer 192 and an etch-stop layer 190 and be connected to the contact structure 150. The via 170 may electrically connect the power interconnection layer 180P and the active region 110 to each other. The via 170 may include a barrier layer 172 and a conductive layer 174. The barrier layer 172 includes, for example, at least one of titanium (Ti), titanium nitride (TiN), tantalum (Ta), tantalum nitride (TaN), tungsten nitride (WN), and tungsten carbon nitride (WCN). The conductive layer 174 may include, for example, at least one of ruthenium (Ru), molybdenum (Mo), tungsten (W), copper (Cu), aluminum (Al), and cobalt (Co).

The interconnection layers 180 may have a line shape or a bar shape extending in the X-direction. The interconnection layers 180 may include a power interconnection layer 180P and a signal interconnection layer 180S. The power interconnection layer 180P may include a pair of power interconnection layers 180P extending in parallel to each other. Signal interconnection layers 180S may be disposed between a pair of power interconnection layers 180P on the same or substantially similar level as the power interconnection layer 180P. Each of the interconnection layers 180 may include a barrier layer 182 and a conductive layer 184. The barrier layer 182 includes, for example, at least one of titanium (Ti), titanium nitride (TiN), tantalum (Ta), tantalum nitride (TaN), tungsten nitride (WN), and tungsten carbon nitride (WCN). The conductive layer 184 may include, for example, at least one of ruthenium (Ru), molybdenum (Mo), tungsten (W), copper (Cu), aluminum (Al), and cobalt (Co).

The interlayer insulating layers 191, 192, and 193 may be disposed on the source/drain regions 120 and the gate structures 130. The interlayer insulating layers 191, 192, and 193 may include a first interlayer insulating layer 191, a second interlayer insulating layer 192, and a third interlayer insulating layer 193 that are sequentially stacked. The etch-stop layers 190 may be disposed between the interlayer insulating layers 191, 192, and 193, respectively. Each of the etch-stop layers 190 and the interlayer insulating layers 191, 192, and 193 may include at least one of a silicon oxide, a silicon nitride, a silicon oxynitride, and a silicon oxycarbide.

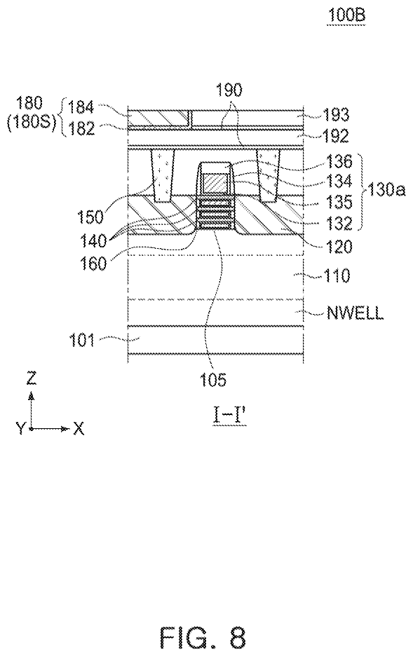

FIG. 8 is a cross-sectional view of a semiconductor device according to an example embodiment. FIG. 8 illustrates a region corresponding to FIG. 7A.

Referring to FIG. 8, a semiconductor device 100B may further include a plurality of channel layers 140, disposed on an active fin 105 of an active region 110 to be vertically spaced apart from each other, and internal spacer layers 160 disposed to be parallel to the gate electrode layer 135. The semiconductor device 100B may include transistors having a gate-all-around structure in which a gate structure 130a is disposed between the active fin 105 and the channel layers 140. For example, the semiconductor device 100B may include transistors having a multi-bridge channel FET (MBCFET™) structure formed by the channel layers 140, the source/drain regions 120, and the gate structure 130a.

The plurality of channel layers 140 may include at least two channel layers 140 disposed on the active region 110 to be spaced apart from each other in a direction, perpendicular to an upper surface of the active fin 105 (e.g., in a Z-direction). The channel layers 140 may be spaced apart from upper surfaces of the active fin 105 while being connected to the source/drain regions 120. The channel layers 140 may have a width the same as or substantially similar to a width of the active fin 105 in the Y-direction, and may have a width the same as or substantially similar to a width of the gate structure 130a in the X-direction. However, according to some example embodiments, the channel layers 140 may have a reduced width such that side surfaces thereof are disposed below the gate structure 130a in the X-direction.

The plurality of channel layers 140 may be formed of a semiconductor material and may include, for example, at least one of silicon (Si), silicon germanium (SiGe), and germanium (Ge). The channel layers 140 may be formed of, for example, the same material as the substrate 101. The number and shape of the channel layers 140, constituting a single channel structure, may vary according to example embodiments. For example, a channel layer may be further disposed in a region, in which the active fin 105 is in contact with the gate electrode layer 135, according to some example embodiments.

The gate structure 130a may be disposed on the active fins 105 and the plurality of channel layers 140 to extend while intersecting the active fins 105 and the plurality of channel layers 140. Channel regions of transistors may be formed in the active fins 105 and the plurality of channel layers 140 intersecting the gate structure 130a. In the present example embodiment, the gate insulating layer 132 may be disposed between the active fin 105 and the gate electrode layer 135, as well as between the plurality of channel layers 140 and the gate electrode layer 135. The gate electrode layer 135 may be disposed on the active fins 105 to fill a gap between the plurality of channel layers 140 and to extend upwardly along the plurality of channel layers 140. The gate electrode layer 135 may be spaced apart from the plurality of channel layers 140 by the gate insulating layer 132.

The internal spacer layers 160 may be disposed side by side with the gate electrode layer 135 between the plurality of channel layers 140. The gate electrode layer 135 may be spaced apart from the source/drain regions 120 by the internal spacer layers 160 to be electrically separated therefrom. Each of the internal spacer layers 160 may have a planar side surface facing the gate electrode layer 135, or may be convexly rounded towards the gate electrode layer 135. The internal spacer layers 160 may be formed of an oxide, a nitride, and an oxynitride, in particular, may be formed a low-k dielectric material.

In some example embodiments, the semiconductor device may include a vertical field effect transistor (FET), which includes an active region extending in a direction perpendicular to the upper surface of the substrate 101 and a gate structure surrounding the active region, in at least one region. In some example embodiments, the semiconductor device may include a negative capacitance FET (NCFET), using a gate insulating layer having ferroelectric characteristics, in at least one region.

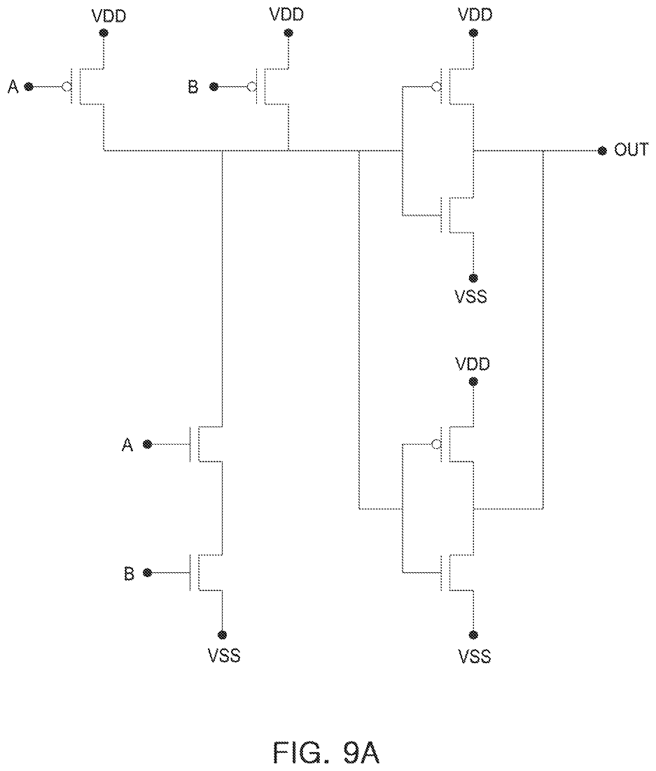

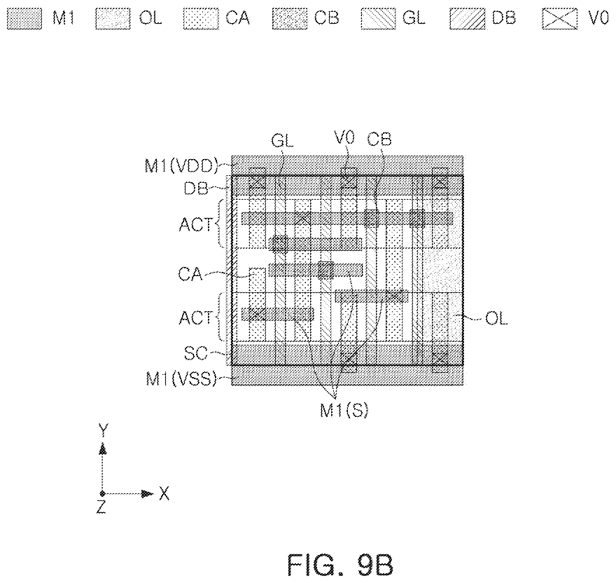

FIG. 9A is a diagram illustrating a circuit provided by a layout of a semiconductor device according to an example embodiment. FIG. 9A illustrates an AND circuit.

FIG. 9B is a layout view of the semiconductor device of FIG. 9A according to an example embodiment. FIG. 9B illustrates a layout corresponding to the AND circuit of FIG. 9A.

The layout of FIG. 9B may be a layout newly designed from a layout of an existing AND circuit, as a result of moving an interconnection line pattern M1(S) into a cell sharing region OL, within a standard cell SC along an X-axis such that the interconnection line pattern M1(S) is disposed outside the cell sharing region OL. The newly designed standard cell SC of FIG. 9B may be disposed to partially overlap another standard cell to share the cell sharing region OL therewith.

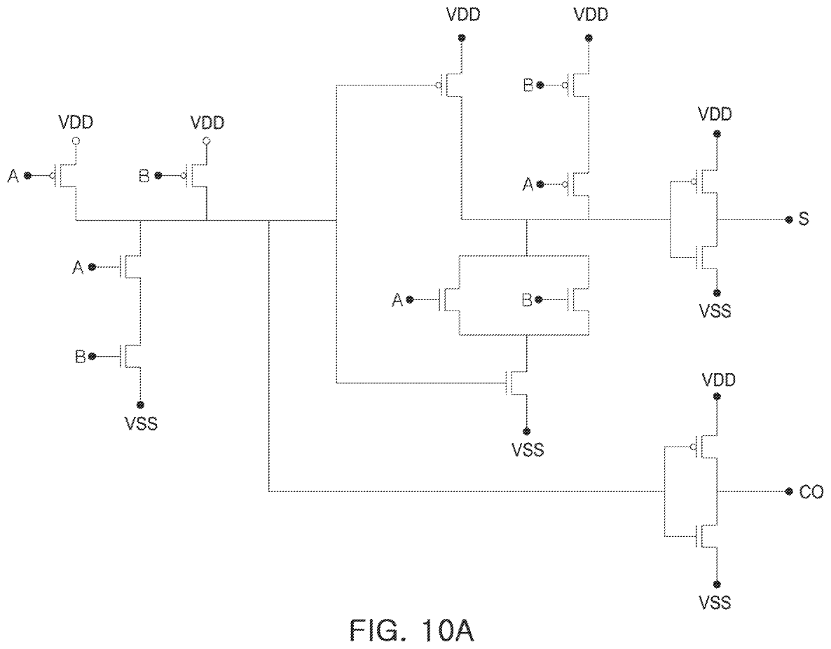

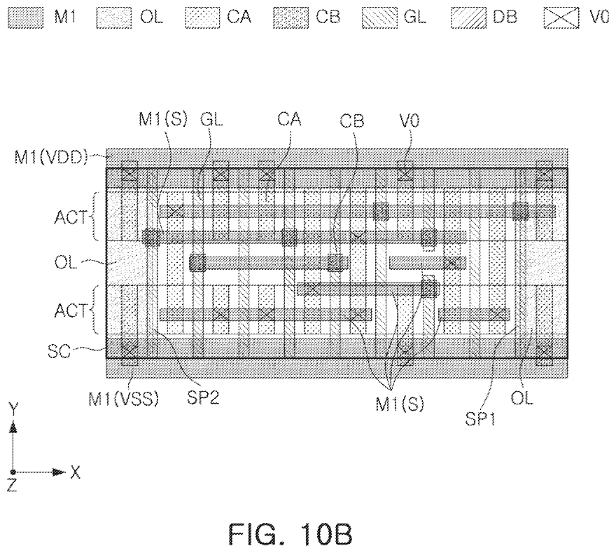

FIG. 10A is a diagram illustrating a circuit provided by a layout of a semiconductor device according to an example embodiment. FIG. 10A illustrates a half-adder (ADDH) circuit.

FIG. 10B is a layout view of the semiconductor device of FIG. 10A according to an example embodiment. FIG. 10B illustrates a layout corresponding to the ADDH circuit of FIG. 10A.

The layout of FIG. 10B may be a layout newly designed from a layout of an existing ADDH circuit, as a result of moving an interconnection line pattern Ml(S into a cell sharing region OL, within a standard cell SC along an X-axis such that the interconnection line pattern M1(S) is disposed outside the cell sharing region OL. The newly designed standard cell SC of FIG. 10B may be disposed to partially overlap another standard cell to share the cell sharing region OL therewith.

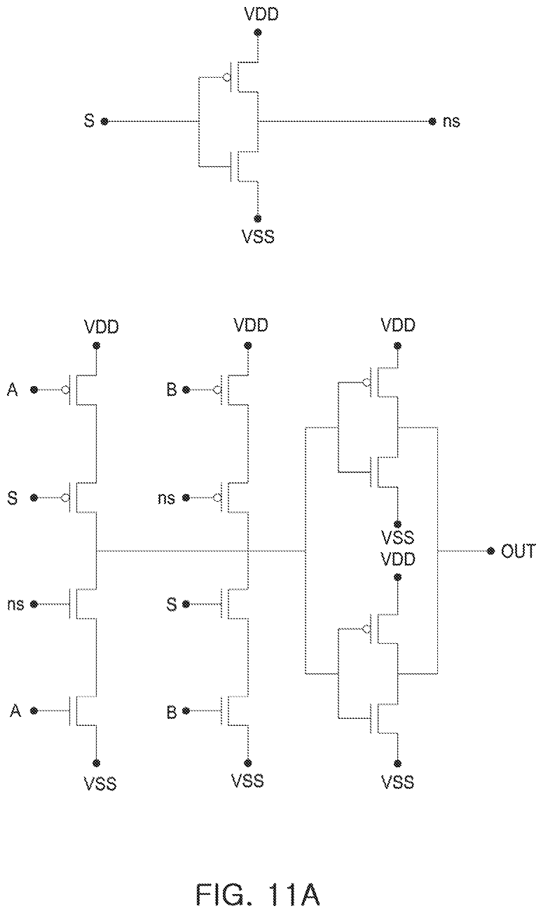

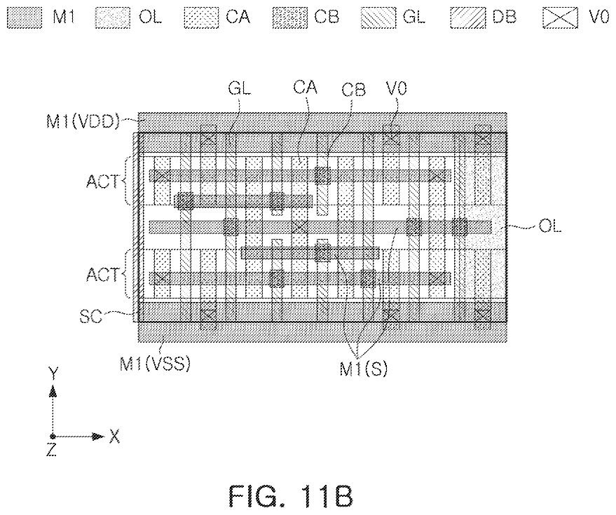

FIG. 11A is a diagram illustrating a circuit provided by a layout of a semiconductor device according to an example embodiment. FIG. 11A illustrates a multiplexer (MUX) circuit.

FIG. 11B is a layout view of the semiconductor device of FIG. 11A according to an example embodiment. FIG. 11B illustrates a layout corresponding to the MUX circuit of FIG. 11A.

The layout of FIG. 11B may be a layout newly designed from a layout of an existing MUX circuit, as a result of moving an interconnection line pattern Ml(S into a cell sharing region OL, within a standard cell SC along an X-axis such that the interconnection line pattern M1(S) is disposed outside the cell sharing region OL. The newly designed standard cell SC of FIG. 11B may be disposed to partially overlap another standard cell to share the cell sharing region OL therewith.

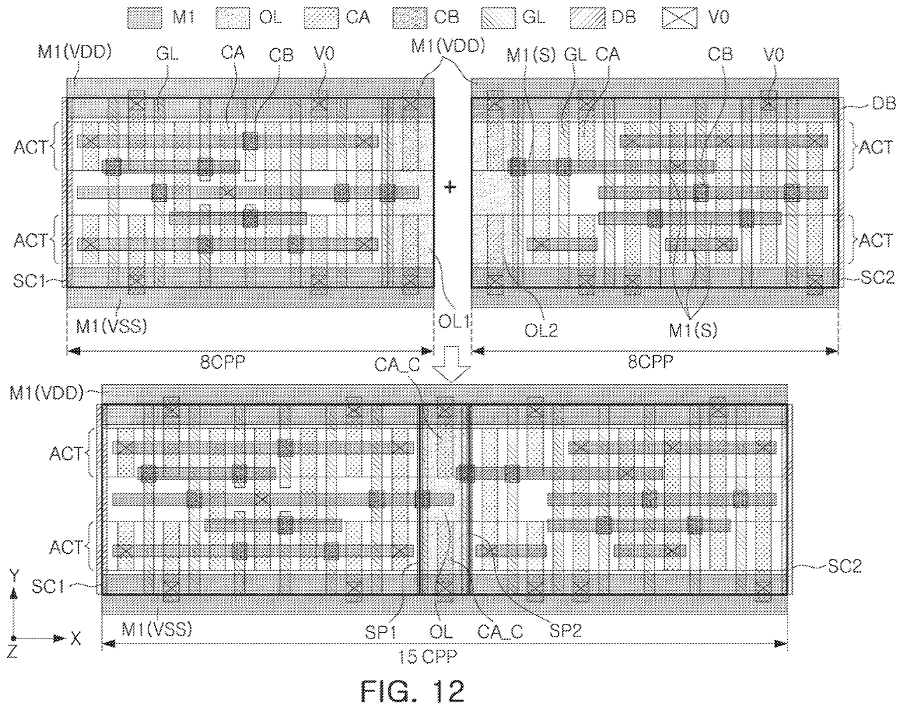

FIG. 12 is a diagram illustrating a process in which standard cells disposed to overlap each other in a layout of a semiconductor device according to an example embodiment.

A process, in which a layout of a first standard cell SC1 corresponding to the MUX circuit and a layout of a second standard cell SC2 corresponding to an AOI circuit are disposed to partially overlap each other, is illustrated in FIG. 12. Because interconnection line patterns M1(S) of the second standard cell SC2 are rearranged, even when the second standard cell SC1 is disposed to partially overlap the first standard cell SC1, an arrangement area of standard cells may be reduced while satisfying a design rule in relation to the interconnection line patterns M1(S) of the first standard cell SC1.

As described above, a layout design of standard cells implemented as various circuits may be modified to reduce an arrangement area of standard cells and to satisfy a design rule of interconnection line patterns. Thus, a routing design margin may be secured.

According to the above-described example embodiments, standard cells sharing a cell sharing region may be disposed to overlap each other, and arrangement of an interconnection line pattern around the cell sharing region may be improved or optimized. Thus, a semiconductor device having an improved degree of integration and improved reliability may be provided.

While some example embodiments have been shown and described above, it will be apparent to those skilled in the art that modifications and variations could be made without departing from the scope of the present inventive concepts as defined by the appended claims.

What is claimed is:

1. A semiconductor device comprising:
a standard cell including active patterns extending in a first direction, gate patterns intersecting the active patterns and extending in a second direction perpendicular to the first direction, and contact patterns being on the active patterns at opposite sides of the gate patterns;
signal line patterns extending in the first direction on the standard cell, arranged in the second direction, and electrically connected to the standard cell; and
a first power interconnection line pattern and a second power interconnection line pattern both extending in the first direction on the standard cell, the first power interconnection line pattern and the second power interconnection line pattern electrically connected to some of the active patterns and configured to supply different voltages, respectively, to the standard cell,
wherein the standard cell includes a first standard cell and a second standard cell, and the first standard cell and the second standard cell partially overlap each other to define a cell sharing region,
wherein the contact patterns include a sharing contact pattern that is in the cell sharing region and is electrically connected to one of the first power interconnection line pattern and the second power interconnection line pattern, and
wherein at least one of the signal line patterns electrically connected to a contact pattern that is closest to the sharing contact pattern among the contact patterns is spaced apart from the cell sharing region.

2. The semiconductor device of claim 1, wherein
the first standard cell has a first cell boundary in the second standard cell and extending in the second direction, and
the second standard cell has a second cell boundary in the first standard cell and extending in the second direction.

3. The semiconductor device of claim 2, wherein the cell sharing region is defined between the first cell boundary and the second cell boundary.

4. The semiconductor device of claim 2, wherein a distance between the first cell boundary and the second cell boundary in the first direction is same as a single pitch between the gate patterns.

5. The semiconductor device of claim 2, wherein the signal line patterns include a signal line pattern that is in the first standard cell and is closer to the second cell boundary than to the first cell boundary.

6. The semiconductor device of claim 2, wherein the signal line patterns include a signal line pattern that is in the second standard cell and is closer to the first cell boundary than to the second cell boundary.

7. The semiconductor device of claim 1, wherein the sharing contact pattern is configured to supply a power supply voltage or a ground voltage to both the first standard cell and the second standard cell.

8. The semiconductor device of claim 1, wherein a diffusion break pattern is absent in the cell sharing region.

9. The semiconductor device of claim 1, further comprising:
gate contact patterns connected to the gate patterns,
wherein at least one of the signal line patterns is connected to the gate contact patterns and overlaps the cell sharing region.

10. The semiconductor device of claim 1, wherein
the sharing contact pattern comprises a first sharing contact pattern on a first active pattern and a second sharing contact pattern on a second active pattern, and
the sharing contact pattern further comprises,
a first via pattern in a region in which the first sharing contact pattern overlaps the first power interconnection line pattern, and
a second via pattern in a region in which the second sharing contact pattern overlaps the second power interconnection line pattern.

11. A semiconductor device comprising:
a standard cell including active patterns extending in a first direction, gate patterns extending in a second direction perpendicular to the first direction, and contact patterns being on the active patterns at opposite sides of the gate patterns; and
interconnection line patterns extending in the first direction and spaced apart from each other in the second direction, on the stand cell,
wherein the standard cell comprises a first standard cell and a second standard cell partially overlapping each other,
wherein a first special boundary is defined on a cell boundary of the second standard cell, in the first standard cell,
wherein a second special boundary is defined on a cell boundary of the first standard cell, in the second standard cell, and
wherein at least one of the interconnection line patterns of the first standard cell is spaced apart from the first special boundary.

12. The semiconductor device of claim 11, wherein at least one of the interconnection line patterns of the second standard cell is spaced apart from the second special boundary.

13. The semiconductor device of claim 11, wherein
the first special boundary overlaps a first gate pattern of the first standard cell, and
the second special boundary overlaps a second gate pattern of the second standard cell.

14. The semiconductor device of claim 13, wherein the contact patterns comprise a single sharing contact or a plurality of sharing contacts between the first gate pattern and the second gate pattern and shared by the first standard cell and the second standard cell. and

15. The semiconductor device of claim 14, further comprising:
a via pattern on the single sharing contact or on each of the plurality of sharing contacts; and
a power interconnection line pattern on the via pattern and extending in the first direction.

16. The semiconductor device of claim 14, wherein
the single sharing contact or the plurality of sharing contacts are in a power source sharing region, in which the first standard cell and the second standard cell overlap each other, to supply a power source to both the first standard cell and the second standard cell.

17. A semiconductor device comprising:
a standard cell including active patterns extending in a first direction, gate patterns extending in a second direction perpendicular to the first direction, first contact patterns being on the active patterns at opposite sides of the gate patterns, and second contact patterns on the gate patterns;
interconnection line patterns extending in the first direction on the standard cell and arranged in the second direction; and
via patterns electrically connecting the first contact patterns and the interconnection line patterns to each other,
wherein the interconnection line patterns comprise a first power interconnection line pattern and a second power interconnection line pattern both extending in the first direction, and the first power interconnection line pattern and the second power interconnection line pattern are configured to supply different voltages, respectively, to the standard cell, and are side by side with each other,
wherein the standard cell comprises a first standard cell and a second standard cell, and the first standard cell and the second standard cell are between the first power interconnection line pattern and the second power interconnection line pattern and partially overlap each other to define a cell sharing region,
wherein the active patterns comprise a first active pattern in the first standard cell and a second active pattern in the second standard cell, and the first contact patterns comprise a first sharing contact pattern on the first active pattern and a second sharing contact pattern on the second active pattern, in the cell sharing region,
wherein the via patterns comprise a first via pattern on the first sharing contact pattern and a second via pattern on the second sharing contact pattern in the cell sharing region,
wherein the first via pattern is in a region in which the first sharing contact pattern overlaps the first power interconnection line pattern, and
wherein the second via pattern is in a region in which the second sharing contact pattern overlaps the second power interconnection line pattern.

18. The semiconductor device of claim 17, wherein
the interconnection line patterns further comprise signal interconnection line patterns extending in the first direction between the first power interconnection line pattern and the second power interconnection line pattern, and
the signal interconnection line patterns comprise a rearrangement interconnection line pattern that is electrically connected to a corresponding one of the first contact patterns, in a region outside the cell sharing region.

19. The semiconductor device of claim 18, wherein the rearrangement interconnection line pattern is spaced apart from a boundary of the cell sharing region.

20. The semiconductor device of claim 17, wherein
the first sharing contact pattern is configured to transmit a first voltage that has been transmitted from the first power interconnection line pattern to each of the first and second standard cells, and
wherein the second sharing contact pattern is configured to transmit a second voltage that has been transmitted from the second power interconnection line pattern to each of the first and second standard cells.
